(19) United States
(12) Patent Application Publication
(10) Pub. No.: US 2026/0338887 A1
(43) Pub. Date: Oct. 29, 2026

(54) SUPPORT APPARATUS FOR A MOVABLE MAGNET OF AN MRI SYSTEM

(71) Applicant: Taumedis Inc., Winnipeg (CA)

(72) Inventors: Darrell Van Mol, East St Paul (CA); Gordon Klimenko, Winnipeg (CA); Michael Lang, Winnipeg (CA); Henry Floreal, Winnipeg (CA); Gong Zhang, Winnipeg (CA)

(21) Appl. No.: 19/562,288

(22) Filed: Mar. 10, 2026

Related U.S. Application Data
(60) Provisional application No. 63/769,407, filed on Mar. 10, 2025.

(51) Int. Cl. G01R 33/34; G01R 33/48

(52) U.S. Cl. CPC G01R 33/34; G01R 33/48

(57) ABSTRACT

A magnetic resonance imaging system includes a cylindrical magnet with a detection system for eliciting nuclear magnetic resonance signals where the magnet is mounted on a support undercarriage for movement relative to the floor. This can include drive tracks on respective sides of the magnet for forward, rearward and turning movement relative to a patient table or can include guided wheels/rollers. A separate lifting system is provided, including compressed air casters or magnetic lift, for lifting the tracks up from the floor. In one arrangement the tracks form the primary support and the lift system acts to allow the magnet to be moved relative to the floor independently of the drive control system. In another arrangement the magnet is lifted primarily by the float and the tracks and/or rotatable drive wheel or roller engaging the floor are used for guiding and steering the support system and the magnet across the floor.

This application claims the benefit under 37 CFR 119(e) of Provisional Application 63/769,407 filed Mar. 10, 2025.

This invention relates to support apparatus for a movable magnet of an MRI system for use in surgical procedures where the magnet is movable across a floor relative to a patient table.

### BACKGROUND OF THE INVENTION

Magnetic resonance imaging (MRI) is a non-invasive imaging modality capable of distinguishing a wide variety of objects based on their intrinsic composition and also is an imaging technique that is capable of providing one-, two-or three-dimensional imaging of the object. A conventional MRI system typically includes a main or primary magnet that provides the main static magnetic field, B0, magnetic field gradient coils and radio frequency (RF) coils, which are used for spatial encoding, exciting and detecting the nuclei for imaging. Typically, the main magnet is designed to provide a homogeneous magnetic field in an internal region within the main magnet, for example, in the air space of a large central bore of a solenoid or in the air gap between the magnetic pole plates of a C-type magnet. The patient or object to be imaged is positioned in the homogeneous field region located in such air space. The gradient field used to convert distance into frequency and the RF coils used to transmit and receive signals from the patient are typically located external to the patient or object to be imaged and inside the geometry of the main or primary magnet(s) surrounding the air space.

Typically the uniform magnetic field B0 generated by the main magnet on the high field MRI systems (>1.0 Tesla) is generated and then remains on for the life of the magnet, although the field maybe boosted every now and then during the magnet's operating life. In conventional MRI devices, the patient is bought to the magnet, placed on a patient couch and then slid into the magnet with the region to be imaged placed as close to the isocenter of the magnet. This requires that the patient be either ambulatory or can be brought to the magnet on a gurney and slid into the magnet. There are many times when the physician would prefer to bring the MRI magnet to the patient since the patient is in a position where he/she should not be moved. Examples include patient undergoing surgical or interventional procedures where the physician needs an image or for patients such as stroke or accident victims who by their condition should not be moved.

Modern neurosurgery encompasses the surgical treatment of many complex conditions such as primary intracranial or spinal neoplasms, lesions of the cranium and cranial base, cerebral vascular disorders including arteriovenus malformations, cavernous angiomas and intracranial aneurysms, and inflammatory conditions. Concurrent with these changes, imaging by computerized tomography, magnetic resonance, positron emission tomography, and magnet wave processing provide greatly improved comprehension of brain structure and functional events. Imaging data have been incorporated into stereotactic space by a number of devices to allow a precise point access and volume comprehension for planning and trans-cerebral navigation, all with striking reduction in operative working corridor size. However, this imaging technology needs to be taken to the operating theatre so that changes that result from brain shift and tissue removal and the extent of surgical procedure can be accommodated.

In U.S. Pat. No. 5,735,278 (Hoult) issued Apr. 7, 1998 is disclosed an innovation in which the magnet is mounted on a support carried from an overhead gantry so as to be movable relative to the patient table to allow the magnet to be brought into an imaging position and then moved away to allow the surgical team to access the patient.

A number of surgical intraoperative MRI devices have been developed based on this innovation with the most popular being that sold by IMRIS. The challenge with this IMRIS device is that the installation requires extensive renovations to the hospital operating theatre which is very expensive and results in the operating theatre being unavailable for a significant period of time.

A further development set out in U.S. Pat. No. 10,987,189 (Zhang and Klimenko) issued Apr. 27, 2021 shows a magnet of reduced weight which can thus be carried on an undercarriage mounted on two tracks for forward, rearward and turning movements carried from the floor. This arrangement has a problem in that any failure of the track drive system such as in the event of a power failure can leave the patient stranded on the table with the magnet surrounding the patient.

The disclosures of the above two US patents are incorporated herein by reference.

### SUMMARY OF THE INVENTION

According to a first aspect of the invention there is provided a magnetic resonance imaging system for obtaining images of a part of the patient comprising:
a cylindrical magnet of magnet wire defining a cylindrical bore within which a part of the patient is located for placement within high magnetic fields generated by the magnet;
a detection system for eliciting and detecting from the part of the patient nuclear magnetic resonance signals in response to the magnetic field; and
a support system arranged to be supported from a floor and mounting the magnet for movement relative to the floor between an imaging position and a retracted position, the support system comprising:
   a gas lift system which applies a lifting force from the floor and carries the weight of the magnet;
   wherein the gas lift system acts to float the magnet relative to the floor so that the lift system does not apply to the magnet guiding forces and steering forces;
   a drive system applying from the floor to the magnet guiding and steering forces.

Preferably the gas lift system comprises two gas lift planks each along a respective side of the magnet and each including a series of spaced gas lift members therealong.

Preferably the gas lift planks include floor engagement members are spaced positions therealong relative to the series of spaced gas lift members.

Preferably the gas lift system comprises a primary lift system used for primary lifting and a secondary lift system used when a failure occurs in the primary lift system. In this arrangement, preferably the primary and secondary lift system are arranged in rows along respective sides of the magnet.

Preferably the drive system comprises at least one rotatable drive member rotatable about a horizontal axis for engaging the floor when raised on the gas lift system for driving the magnet across the floor. In this arrangement, preferably the drive system comprises two sets of rotary members on respective sides of the magnet with differential rotation speed for steering. In this arrangement, preferably the rotary members are spring biassed into engagement with floor in both raised and lowered positions of the support system.

Preferably the drive system includes a back up in the event of failure.

Preferably the drive system comprise a guide track applied on the floor and a camera on the support system supplying an image to a controls system for following the guide track.

Preferably the support system comprises a guide pin at a center of the support system for engaging a receptacle at the floor in the retracted position for rotating the support system and the magnet around an axis of the guide pin.

Preferably the support system comprises first and second support plates at the floor at the imaging and retracted positions for receiving loading forces from the gas lift system.

Preferably the support system includes at least one seismic clamp for engaging a receptacle in the floor at the imaging portion for connecting the support system and the magnet to the floor.

Preferably the support system includes resilient support elements between the support system and the magnet.

According to a second aspect of the invention there is provided a magnetic resonance imaging system for obtaining images of a part of the patient comprising:
a cylindrical magnet of magnet wire defining a cylindrical bore within which a part of the patient is located for placement within high magnetic fields generated by the magnet;
a detection system for eliciting and detecting from the part of the patient nuclear magnetic resonance signals in response to the magnetic field; and
a support system arranged to be supported from a floor and mounting the magnet for movement relative to the floor, the support system comprising:
   a lift system which applies a lifting force from the floor and carries at least some of the weight of the magnet at least some of the time;
   a drive control system, separate from the lift system, applying to the magnet guiding forces and steering forces operated by signals from a drive input control.

That is the support system operates from the floor rather than from an overhead gantry and includes both a lift system for providing a lift from the floor and a separate drive control system which acts to control the movement of the magnet while it is lifted.

In one arrangement, the lift system acts to float the magnet relative to the floor so that the lift system does not apply to the magnet the required guiding forces and steering forces. The floating action is preferably provided by an air lift system such as air castors or disks but other lift system can bs used such as those using magnetic levitation. However this float system requires that the movement is not free which would allow the heavy magnet to become uncontrolled but involves a control system which applies guidance or directional forces and also steering forces so that the magnet moves to the require location. As described hereinafter the separate drive control system can comprise a dual track arrangement which uses skid steer principles to guide and move the magnet. Alternatively the drive control system can use rollers or wheels to apply the guide forces to the magnet from the floor.

That is preferably the drive control system includes components in engagement with the floor to apply the steering forces relative to the floor. This avoids the use of rails which are to be avoided since they interfere with the integrity of the floor, provide trip hazards and limit the movement to certain prescribed directions along the rails.

In one arrangement, the drive control system provides a primary lifting and guiding system and the lift system acts to lift the magnet up from the floor sufficiently to allow the magnet to be moved on the lift system relative to the floor independently of the drive control system. This can be used as a back-up or safety system in the event that the primary drive system fails or is otherwise inactive. In such a situation it is essential that the magnet can still be moved to avoid a situation where the magnet is operative and in a location where the high magnetic field causes safety issues or even catastrophic damage. That is in this arrangement, the drive control system forms a primary support system for lifting and guiding the magnet and wherein the lift system is used when the drive control system is inactive. In this arrangement the primary lift and drive system can comprise the double track system described in detail herein and the secondary lift system comprises an air float system which acts to lift the magnet off the primary drive system for independent movement. The use of an air lift system allows the lifting force to be provided by a compressed air source which can be used in the event of a loss of power to drive the primary system.

In an alternative arrangement, the lift or float system can be used to provide a majority of a lifting force to support the weight of the magnet while the drive control system controls guiding and steering. In this way a float system can be provided using air floatation or magnetic levitation and the steering or guiding action provided by a separate system independent of the lifting action.

That is the lift system acts to float the magnet relative to the floor so that the lift system does not apply to the magnet guiding forces and steering forces and the drive control system comprises at least one drive track wrapped around end guide members and with a lower track run engaging the floor. This can use a skid steer system which allow a very effective and variable steering action. Alternatively the drive control can be provided by rollers or wheels in contact with the floor. Yet further a guide system using direction control arms can be used which engage elements in the room such as walls or ceiling to ensure the required directional control. Again it is desirable to avoid use of rails.

According to a third aspect of the invention there is provided a magnetic resonance imaging system for obtaining images of a part of the patient comprising:
a cylindrical magnet of magnet wire defining a cylindrical bore within which a part of the patient is located for placement within high magnetic fields generated by the magnet;
a detection system for eliciting and detecting from the part of the patient nuclear magnetic resonance signals in response to the magnetic field; and
a support system arranged to be supported from a floor and mounting the magnet for movement relative to the floor, the support system comprising:
   drive arrangements for engaging the floor and carrying the magnet;
   the drive arrangements arranged to be driven by a drive control system;
   and a separate lifting system for lifting the drive arrangements and the magnet carried thereby up from the floor sufficiently to allow the magnet to be moved relative to the floor independently of the drive control system of the drive arrangements.

In a preferred arrangement, the separate lifting system uses a compressed gas such as compressed air which can be supplied in a containment cylinder to allow the lifting system to be operated independently of power to the magnet and the support system. In this way the lifting system can be operated manually on failure of the drive arrangements and/or the drive control system to ensure safe movement of the magnet to a storage position.

Preferably the lifting system includes a plurality of pads where the compressed gas passes into the pads and escapes around the pads to lift the pads from the floor. In this arrangement, each pad can be of the type which includes a membrane which provides an annular surface which sits on the floor and the supply of gas escapes around an exterior of the annular surface. That is the separate lifting system can comprise a plurality of gas casters set out in an array of at least three and typically four such casters.

Preferably the lifting system also includes at least one drive member rotatable about a horizontal axis for engaging the floor when raised on the air casters for driving the support system and the magnet across the floor. This can be formed by a roller mounted on a center axis along the magnet or a pair of wheels spaced each on a respective side of the center axis. Preferably the rotatable drive rollers or wheels include one at the front and one at the rear and are movable upwardly and downwardly so as to be spaced from the floor when the magnet is carried on the drive tracks and so as to engage the floor when the support system is lifted. Preferably the drive member is driven by air motor so that it can receive power from the same source as the air casters.

Preferably the drive to the magnet is provided by a pair of drive tracks where each track is wrapped around end guide members and each has a lower track run engaging the floor. These are typically located along or adjacent a respective side of the magnet and the drive control system is arranged to simultaneously said drive arrangements for forward and rearward movement and is arranged to drive said drive arrangements differentially for turning movement.

Preferably the drive tracks and the lifting system are arranged to engage a planar floor so as to avoid the use of guide rails or the like and to avoid modifications to the floor. However the drive may include rails.

Typically the support system includes an undercarriage including resilient mounting pads for attachment to the magnet.

### BRIEF DESCRIPTION OF THE DRAWINGS

One embodiment of the invention will now be described in conjunction with the accompanying drawings in which:

FIG. 1 is an isometric view of an operating theater having an operating table and an MRI imaging magnet mounted on a support system according to the present invention for movement of the magnet relative to the theater and particularly the operating table.

FIG. 2 is an isometric view of the magnet and a first embodiment of the support system of FIG. 1.

FIG. 3 is an isometric view from the top and front of the support system of FIG. 1.

FIG. 4 is an isometric view from the bottom and front of the support system of FIG. 1.

FIG. 5 is an isometric view of a detail of the system of FIG. 4 showing a device for raising and lowering movement of a drive roller.

FIG. 6 is a cross-sectional view along the lines 6-6 of FIG. 4 showing the details of the drive roller.

FIG. 7 is a cross-sectional view along the lines 7-7 of FIG. 4 showing the details of the air casters.

FIG. 8 is an isometric view of the magnet and a second embodiment of the support system of FIG. 1.

FIG. 9 is an isometric view from the bottom and front of the support system of FIG. 8.

FIG. 10 is a cross-sectional view through one air caster of a type which can be used in the present invention.

FIG. 11 is a schematic isometric view of a further embodiment according to the invention showing one half only of the system relative to a center line.

FIG. 12 is a schematic plan view of a further embodiment according to the invention showing some components in phantom to view to show the key elements of the apparatus.

FIG. 13 is a side elevational view of one air lift plank of the embodiment of FIG. 11.

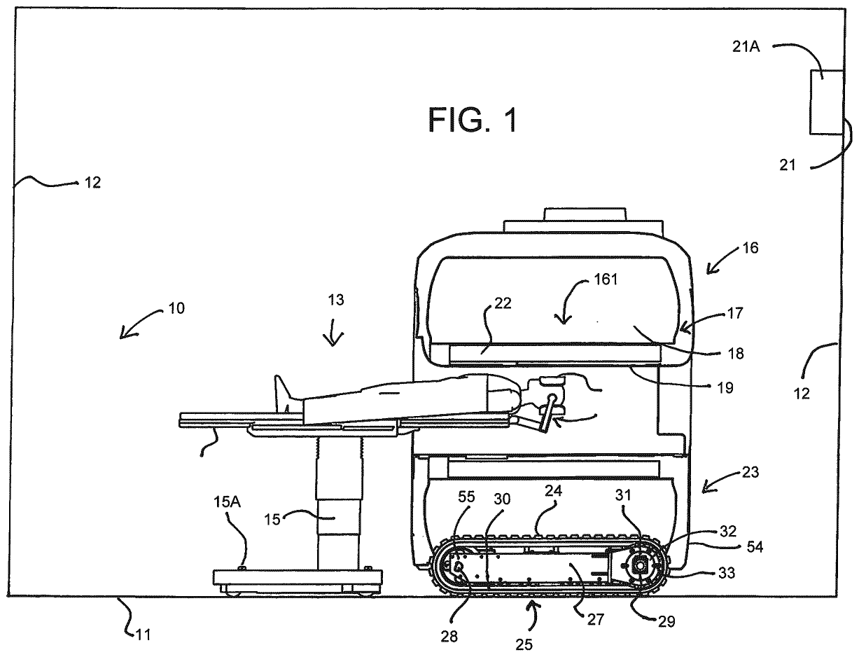

In the drawings like characters of reference indicate corresponding parts in the different figures.

### DETAILED DESCRIPTION

The apparatus for surgical procedures in the embodiment of the Figures includes an operating room 10 having a floor 11 and walls 12 containing an operating table 13 for receiving a patient for a surgical procedure. The table includes a table top 14 on which the patient lies and an upstanding support 15 which is typically adjustable to move the patient to a required position. Constructions of suitable tables are well known in the prior art.

The table cooperates with a magnetic resonance imaging system 16 for obtaining images of a part of the patient at a series of times through the surgical procedure. The images are taken after part of the surgery to assess progress in an analysis by the surgical team to allow the surgical team to monitor the progress of the surgery.

The magnetic resonance imaging system 16 includes a magnet system 17 comprising a cylindrical magnet 18 of magnet wire defining a cylindrical bore 19 within which a part of the patient is located for placement within high magnetic fields generated by the magnet. A control system 21A is provided within the room inside a suitable container or storage module 21 at one side of the room. The control system operates the MRI system and includes a computer and display monitor for decoding and displaying the detected signals using computer operated programs for decoding the various signals to generate images and for operating the RF system, the field of the magnet and other components conventional in this type of system.

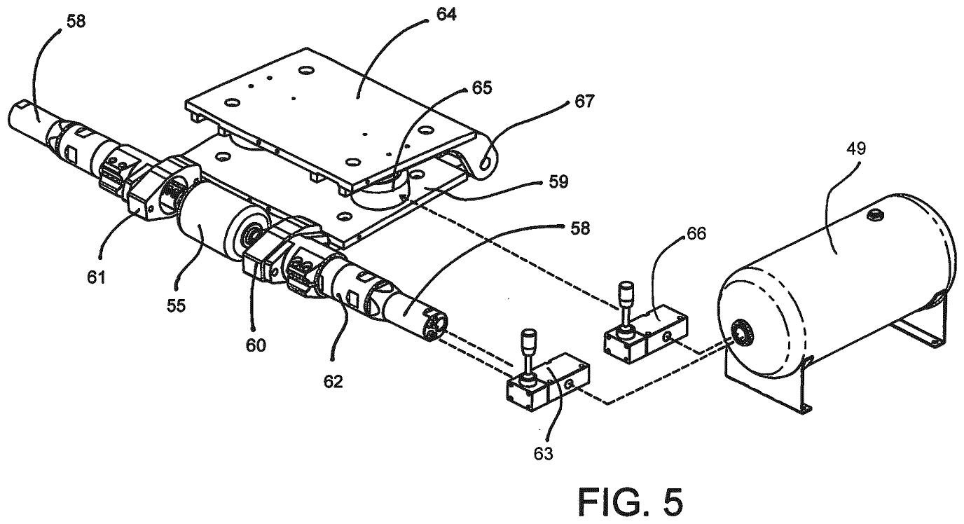

A radio frequency transmission and detection system 22 is shown in FIG. 5 for eliciting and detecting from the part of the patient nuclear magnetic resonance signals, in response to the magnetic field, including an RF probe located adjacent to the head of the patient.

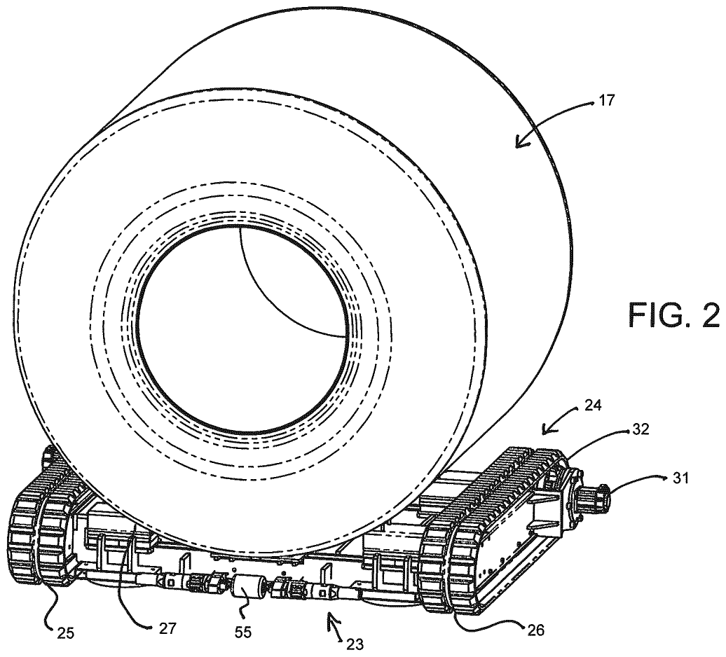

The magnet is mounted on a support system 23 mounting the magnet for movement relative to the table in a direction away from the first end of the table from a first position shown in FIG. 2 at or partly over the table to a second position remote from the table. The second portion is at one wall 12 so as to be well away from the table to ensure the surgeon is not impeded by the presence of the magnet during the surgery.

Thus the first position of the magnet is arranged such that the head, or other part to be imaged, of the patient is positioned in the magnetic field of the magnet while the patient remains in place on the table. Thus the second position of the magnet is arranged such that the magnet is spaced from the first end of the table by a distance sufficient to allow the surgical team to move around the first end of table and to each side of the table to access the patient and sufficient to allow to allow the surgical team to carry out the surgical procedure.

As set forth above, the magnet 17 is designed and arranged as a simple construction of relatively light weight and small size to enable it to be introduced into an existing operating theater and moved between the two positions within the room. Thus the magnet is primarily designed for surgery within the operating room and remains in the room when used in a single room arrangement.

In this arrangement the magnet uses preferably a superconducting material of a suitable material such as magnesium di-boride or Niobium-Tin or Niobium-Titanium which is superconducting at around or below 40 degrees absolute (Kelvin) and hence can be cooled by a cooling system to superconductivity without use of liquid helium.

That is a magnet 17 of this material is cooled by a vacuum cryo-cooling system 25 having a vacuum pump 26 driven by electricity where the pump itself is cooled by a flow of cooling water. Arrangements of this type are previously known to persons skilled in this art so that further explanation is not required.

This weight and dimension of magnet allows the magnet to be carried on a track system described later supported from the floor of a conventional operating theater applying suitable loads to the structure of the building without additional structural stiffening or supporting components. Thus a load of a minimum of 6000 lbs can be spread over a floor area of 20 to 35 sq feet using the tracks to spread the load without overloading the existing floor structure.

As shown in the figures, the support 23 for the magnet includes a track mover supported from the floor 11 mounting the magnet for movement relative to the table.

The support system comprises first and second endless drive tracks 25, 26 each along or adjacent a respective side of the magnet and carried on an undercarriage 27 of the magnet. Each track is wrapped around end guide members 28, 29 and each has a lower track run 30 engaging the floor.

Each of the drive tracks is driven by a servo motor 31 driving through a gear box 32 a sprocket 33 engaging the track. The servo motor avoids the use of hydraulics and ensures very accurate control of the movement of the tracks. The servo motors are controlled by a drive system (not shown) so that when the drive tracks are driven simultaneously this provides accurate forward and rearward movement. When the tracks are driven differentially this will provide a turning movement either to change direction of movement or to rotate around a vertical axis. The drive system uses sensors (not shown) located on the undercarriage 27 to detect a beam or line or mark, such as a laser beam to direct the tracks to carry the magnet to a required location. When moving toward the table it is important that the magnet moves accurately along the line of the table to avoid collisions with the table or patient. Thus sensors on each side and at front and rear of the magnet ensure directional movement along the required direction and immediately detects any deviation or twisting from a required path. In order to provide accurate guidance, there are at least two transversely spaced guide lines either at the floor or at table height which are detected by sensors at a front and rear of the magnet.

As described hereinafter, in the storage module, rotation of the magnet about a fixed center vertical axis is obtained by driving the drive tracks in accurately opposed directions.

The left and right side tracks 25, 26 are thus driven by servo motors 31 which during rotation are engaged in the opposite directions causing the magnet to do precise rotation preferably while inside the storage module but in some cases at other locations between the different operation locations. Laser guided sensors are provided which detect any variance from the required accurate rotation and provide motor compensation to maintain accuracy. This allows the magnet to do precise 180° rotation about a fixed vertical axis.

The drive tracks 25 and 26 and particularly the drive motors 31 actuating the drive thereto are controlled by a control system 31A mounted on the support at a suitable location.

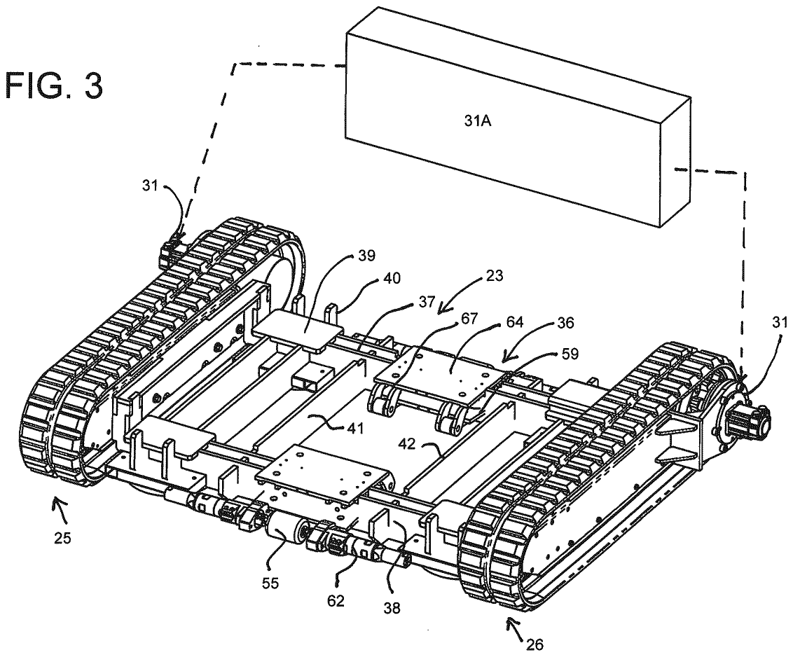

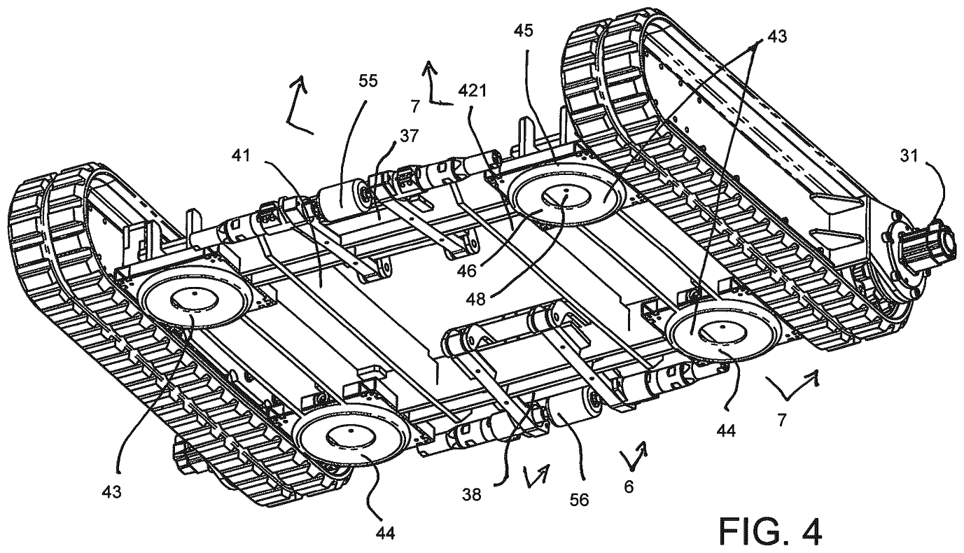

Turning now to FIGS. 3 to 8, the support system 23 includes an undercarriage frame 36 defined by front and rear beams 37 and 38 extending across the magnet at right angles to a center axis of the magnet. Each beam carries two mounting pads 39 so that there are four mounting pads 39 arranged at four corners of the magnet base. At each mounting pad is provide an upstanding locating lug 40 so that the magnet sits stably on the undercarriage held in place by the pads and lugs. The beams 37 and 38 are connected by front to rear structural plates 41 and 42 to hold the structure stable.

The support system further includes a separate lifting system 43 for lifting the drive tracks 25, 26 and the magnet carried thereby up from the floor 11 sufficiently to allow the magnet to be moved relative to the floor independently of the drive control system 31A of the drive tracks. That is the undercarriage is lifted just sufficiently to clear the tracks from the floor so that the tracks can slide over the floor without significant friction.

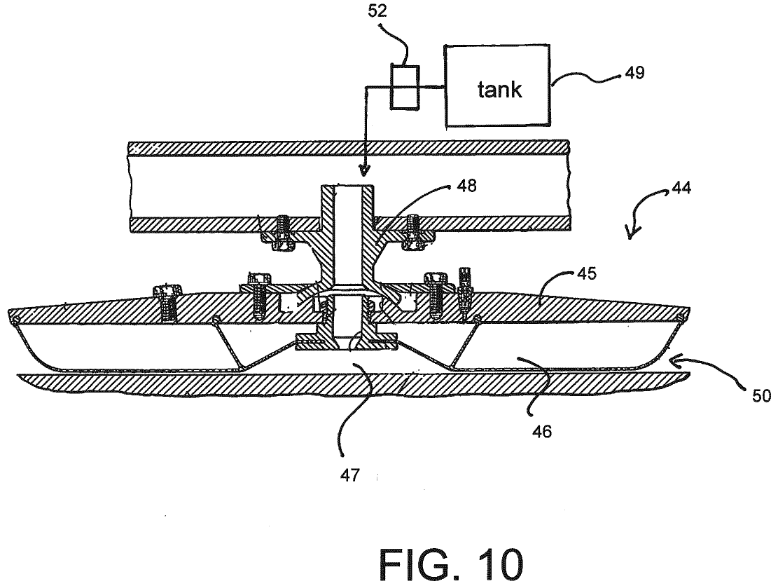

The separate lifting system 43 includes four pads or air casters 44 where the compressed gas passes into the pads and escapes around the pads to lift the pads from the floor. One such air caster is shown in cross-section in FIG. 10 which includes a flat base plate 45 carrying an annular membrane 46 surrounding a central recess 47 into which compressed air enters from a gas supply tank 49 though a duct 48. Thus each pad comprises the annular membrane 46 which provides an annular surface which sits on the floor and the supply of gas escapes underneath the membrane and around an exterior of the annular surface at 50. This acts to lift the gas caster off the floor surface sufficiently to raise the tracks so that they are no longer in frictional engagement with the floor. Each of the four casters is thus powered by the tank 49 of compressed gas which can be operated by a valve 52.

The valves 52 of the lifting system can be operated manually on failure of the drive tracks 25, 26 and/or the drive control system 31A.

In addition the lifting system 23 includes two rotatable drive rollers 55 and 56 carried on the undercarriage at the front and rear respectively and each rotatable about a horizontal axis across the undercarriage at right angles to the magnet center axis for engaging the floor when raised on the air casters 44 for driving the support system and the magnet across the floor. The rollers 55 and 56 are mounted centrally of the undercarriage on the center axis along the magnet.

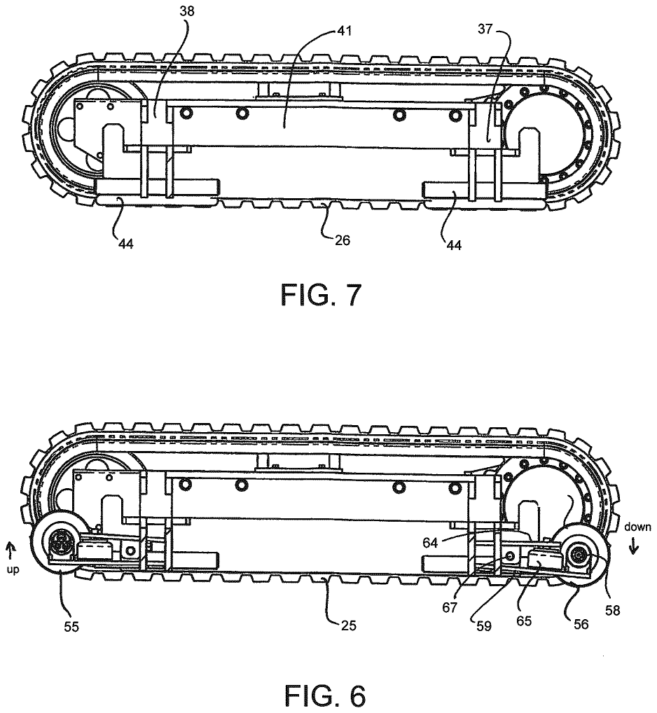

The rollers 55 and 56 as shown in FIG. 6 are movable upwardly and downwardly so as to be spaced from the floor, as shown in the left, when the magnet is carried on the drive tracks and so as to engage the floor, as shown in the right, when the magnet is lifted by actuation of the air casters.

As shown best in FIG. 5, the roller 55 is mounted on an axle 58 carried on a plate 59 by bearings 60 and 61. The axle and the roller are driven by an air motor 62 which also receives drive air from the compressed air tank 49 via a control valve 63. The plate 59 is pivotally connected by a hinge 66 to a second plate 64 which is part of the undercarriage and attaches to the magnet. Gas bag actuators 65 can be expanded by gas from the tank 49 though a control valve 66 so as to lower the plate 59 and this the roller 55 carried thereby into engagement with the floor.

In tis way, in the event that the drive tracks are inoperative, the magnet carried on the undercarriage can be lifted by the gas castors so that the tracks no longer frictionally engage the floor. In this way the magnet is in flotation mode and can be manually pushed in any direction as required. If it is required to drive the magnet forwardly or rearwardly along its axis, which is the typical movement require din such a situation, the rollers 55 are lowered by actuating the gas bags 65 and rotated by actuating the air motors 62.

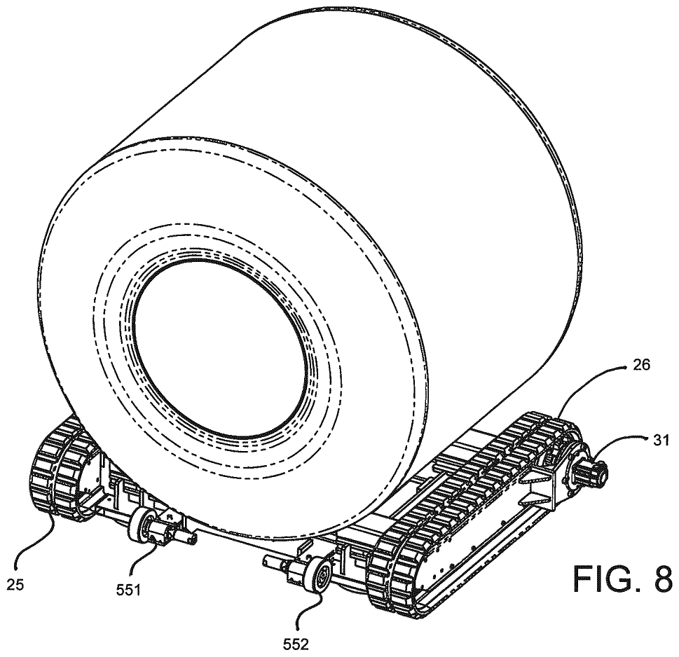

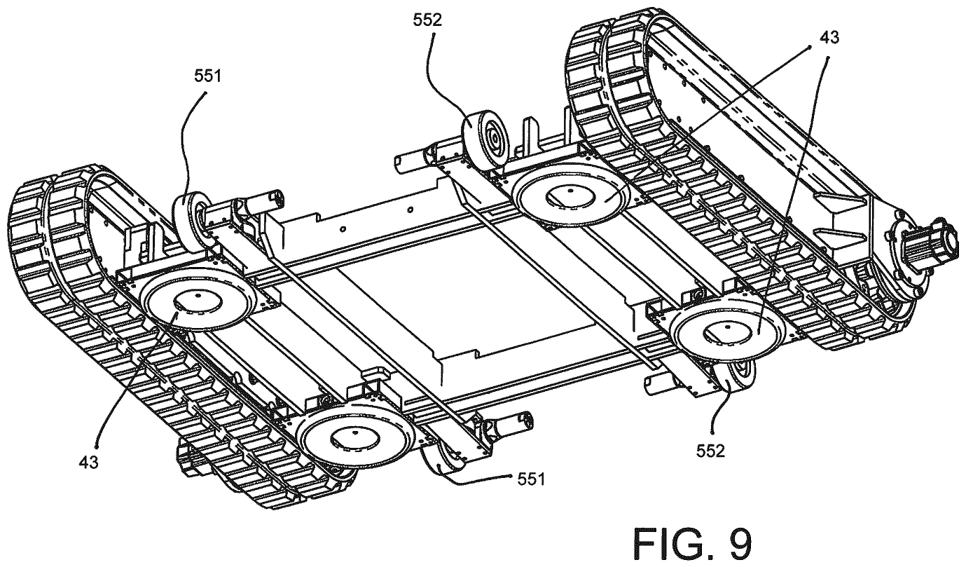

In the second embodiment of FIGS. 8 and 9, the structure is the same except that the single rollers 55 are replaced by a pair of wheels 551 and 552 spaced each on a respective side of a center axis along the magnet. The wheels are raised and lowered in the same way using gas bag actuators and are driven by separate air motors potentially allowing some additional steering action when the motors are driven differentially.

Thus as shown in the Figures there is provided a magnetic resonance imaging system 16 including a cylindrical magnet 18 of magnet wire defining a cylindrical bore 19 within which a part of the patient is located for placement within high magnetic fields generated by the magnet. A detection system 22 is provided for eliciting and detecting from the part of the patient nuclear magnetic resonance signals in response to the magnetic field.

The novel features herein relate to the support system 23 arranged to be supported from the floor 11 and mounting the magnet for movement relative to the floor.

This includes the lift or floating system 43 which applies a lifting force from the floor 11 and carries at least some of the weight of the magnet at least some of the time. There is also provided a drive control system which can include tracks 25, 26, separate from the lift system, applying to the magnet guiding forces and steering forces operated by signals from a drive input control 31A. That is the float system 43 can in some cases act as a primary lift system to carry all or most of the weight of the magnet when it is required to be moved. In other cases as discussed in detail above, the lift system 43 can act as a secondary system in the event that the track lift system is inactive.

That is both lift and guide system of the support system operate from the floor rather than from an overhead gantry and includes both a lift system for providing a lift from the floor and a separate drive control system which acts to control the movement of the magnet while it is lifted.

In one arrangement, the lift float system 43 acts to float the magnet relative to the floor so that the lift/float system does not apply to the magnet the required guiding forces and steering forces. The floating action is preferably provided by an air lift system such as air castors or disks 44. However other lift systems can be used including different shapes of air lift elements including elongate bars or planks. In addition systems using other lift modalities can be used such as those using magnetic levitation.

However this float system provided by the air casters 44 do not themselves include any guidance and the magnet could therefore move in unintended directions. The system thus requires that the movement is not free which would allow the heavy magnet to become uncontrolled but involves a control system which applies guidance or directional forces and also steering forces so that the magnet moves to the required location. As described above the separate drive control system can comprise the dual track arrangement 25, 26 which uses skid steer principles to guide and move the magnet. Alternatively the drive control system can use rollers or wheels 56 to apply the guide forces to the magnet from the floor.

That is the drive control system includes components including tracks 25, 25 or wheels/rollers 56 in engagement with the floor to apply the steering forces relative to the floor. This avoids the use of rails which are to be avoided since they interfere with the integrity of the floor, provide trip hazards and limit the movement to certain prescribed directions along the rails.

In one arrangement as described herein, the drive control system provides a primary lifting and guiding system provided by the tracks 25, 26 and the lift system provided by the air castors acts to lift the magnet up from the floor sufficiently to allow the magnet to be moved on the lift system relative to the floor independently of the drive control system 31A. This can be used as a back-up or safety system in the event that the primary drive system provided by the tracks 25, 26 fails or is otherwise inactive. In such a situation it is essential that the magnet can still be moved to avoid a situation where the magnet is operative and positioned at a location where the high magnetic field causes safety issues or even catastrophic damage. That is in this arrangement, the drive control system provided by tracks 25, 26 forms a primary support system for lifting and guiding the magnet and wherein the lift system is used when the drive control system is inactive. In this arrangement the primary lift and drive system can comprise the double track system described in detail herein and the secondary lift system comprises an air float system which acts to lift the magnet off the primary drive system for independent movement. The use of an air lift system allows the lifting force to be provided by a compressed air source which can be used in the event of a loss of power to drive the primary system.

In an alternative arrangement, the lift or float system 43 can be used to provide a majority of a lifting force to support the weight of the magnet while the drive control system provide by the tracks and/or the guide wheels controls guiding and steering. In this way a float system can be provided using air floatation or magnetic levitation and the steering or guiding action provided by a separate system independent of the lifting action.

That is the lift system 43 acts to float the magnet relative to the floor so that the lift system does not apply to the magnet guiding forces and steering forces and the drive control system comprises at least one drive track 25, 26 wrapped around end guide members and with a lower track run engaging the floor. This can use a skid steer system which allow a very effective and variable steering action. Alternatively the drive control can be provided by rollers or wheels in contact with the floor.

Yet further a guide system for the otherwise uncontrolled float system can be provided using direction control arms (not shown) which engage elements in the room such as walls or ceiling to ensure the required directional control. Again it is desirable to avoid use of rails.

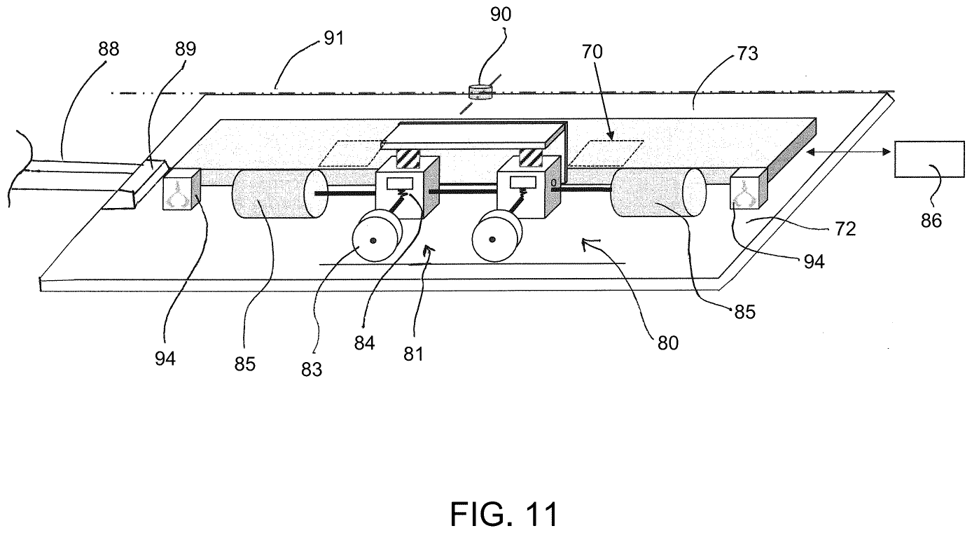

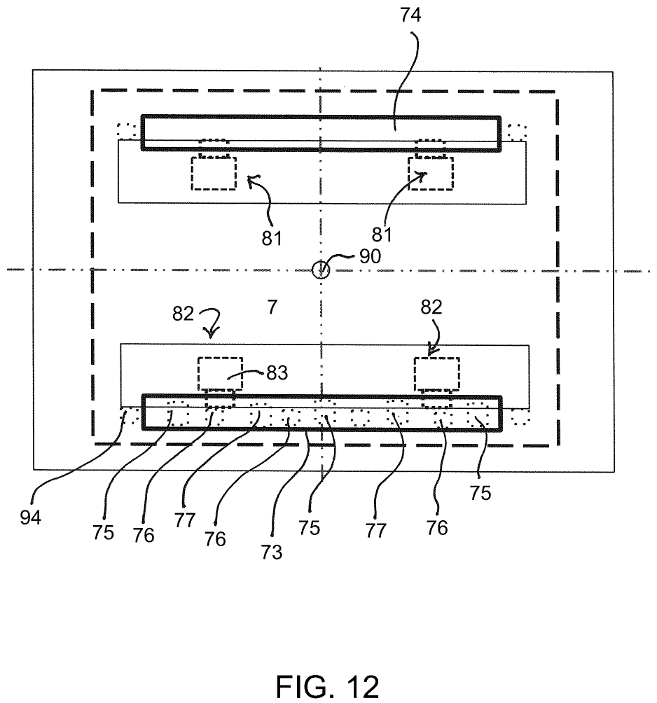

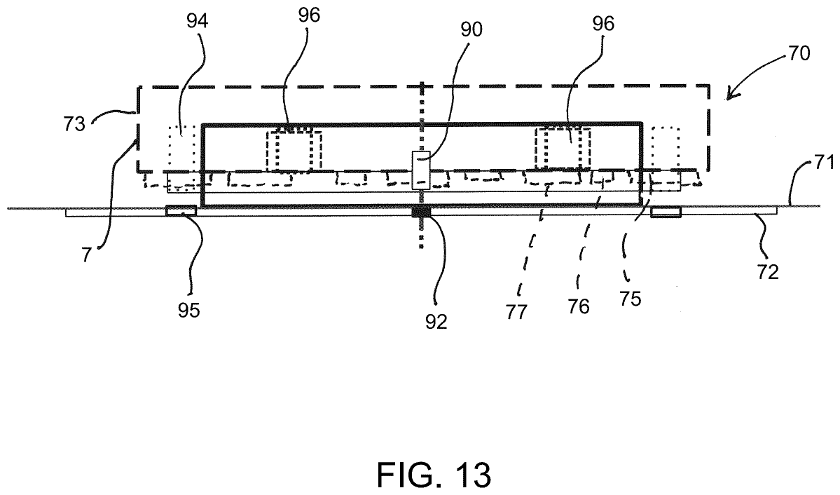

As shown in FIGS. 11 to 13 there is provided a gas lift system 70 which applies a lifting force from the floor 71 and particularly relative to a plate 72 received within the floor and carries the weight of the magnet. The gas lift system 70 comprises two gas lift planks 73, 74 each along a respective side of the magnet and each including a series of spaced gas lift members 75 therealong of the type disclosed above where the gas lift system 70 acts to float the magnet relative to the floor 71. The gas lift planks 73 include floor engagement members or disks 76 spaced positions therealong relative to the series of spaced gas lift members 75 which engage the floor plate 72 when the lift system is shut off.

The gas lift system defined by the planks comprises a primary lift system defined by the lift members 75 used for primary lifting fed supplied by a first compressed gas supply operated by a valve and a secondary lift system supplied by a second compressed gas supply operated by a second valve defined by secondary lift members 77 used when a failure occurs in the primary lift system. That is the primary and secondary lift system are arranged in rows along respective sides of the magnet.

The system further includes a drive system 80 applying from the floor to the magnet guiding and steering forces which comprises two sets 81 and 82 of rotatable drive wheels 83 rotatable about a horizontal axis for engaging the floor when raised on the gas lift system for driving the magnet across the floor. The two sets 81 and 82 of rotary members on respective sides of the magnet are controlled by a control system with differential rotation speed for steering. The wheels 83 are spring biassed by springs 84 into engagement with floor in both raised and lowered positions of the support system. The drive wheels 83 are driven by electric or air driven motors 85 operated by the control system. The drive system includes a back up drive 86 in the event of failure of the primary drive system. This can be a manual crank which is used only in a failure mode to ensure that the magnet is returned to the retracted position.

The drive system further comprises a guide track 88 applied on the floor 71 and a camera 89 on the support system supplying an image to a control system for following the guide track 88 by operating the steering effect caused by the differential speed of the ground wheels.

The support system comprises a guide pin 90 at a center of the support system on a center line 91 for engaging a receptacle at the floor in the retracted position for rotating the support system and the magnet around an axis of the guide pin. The pin 90 is used in the retracted position on the plate 72 for engaging a receptacle 92 at the floor 71 in the retracted position for locating the magnet in the retracted position and for rotating the support system and the magnet around an axis of the guide pin. In this way the magnet can be rotated to different angles to cooperate with different rooms.

The support system includes at least one seismic clamp 94 for engaging a receptacle 95 in the floor at the imaging portion for connecting the support system and the magnet to the floor.

The support system further includes resilient support elements 96 between the support system and the magnet.

The arrangement described above provides the following key features:

The system includes a floor anchor plate located at each parked position for imaging and retraction.

Possible parking plate embedded in the floor under the parked imaging positions which distributes the MRI load over a larger floor area (e.g., 5′×10′) which is less obtrusive to the hospitals floor loading. It also provides a pivot point for rotation of the MR. It also provides embedded rods for the Seismic anchor option to latch onto if the Seismic Option (TBD) is selected.

The drive Wheels can be outboard or inboard with 2 or 3 per side.

The springs push wheel assembly into floor at all times.

Seismic anchors are provided at all times for locating the magnet against floor movement by earthquake or the like. Fasten mover assembly to MRI.

Gearmotor 85 is placed outside of Vibration pads 96.

An Air cylinder pushes a pin or tapered bearing into the centre receptacle of floor plate that provides an accurate axis of rotation.

The floor plate present in all imaging positions with Seismic Anchor rods and rotational tapered bearing receiver present. The mover however might not have the optional seismic or rotational options.

The anchors can be modified since we will have to do OSHPD shaker table testing.

Plate embedded in the floor: Does 3 things: a) distributes MR load over a larger floor area.; b) provides floor depression for axis of rotation (optional, home position only); c) provides grabbing points for (optional) Seismic anchor claws to affix to.

The air Plank Assembly provides primary lift and backup failsafe lift. The MR load rides on a cushion of air.

Seismic Anchors (1 of 4): Attaches MR to Air Plank Assembly

Vibration Pad location (1 of 4) MR's load sits on these pads which rest on the air plank assembly

Air Plank Drive Assembly (1 of 2): Provides primary precision drive and steering and backup failsafe drive for the MR locating tapered hole as part of embedded floor plate (1). A tapered bearing descends into this floor depression and allows a defined axis of rotation when multi room iOR imaging required.

1. A magnetic resonance imaging system for obtaining images of a part of the patient comprising:
a cylindrical magnet of magnet wire defining a cylindrical bore within which a part of the patient is located for placement within high magnetic fields generated by the magnet;
a detection system for eliciting and detecting from the part of the patient nuclear magnetic resonance signals in response to the magnetic field; and
a support system arranged to be supported from a floor and mounting the magnet for movement relative to the floor between an imaging position and a retracted position, the support system comprising:
a gas lift system which applies a lifting force from the floor and carries the weight of the magnet;
wherein the gas lift system acts to float the magnet relative to the floor so that the lift system does not apply to the magnet guiding forces and steering forces;
a drive system applying from the floor to the magnet guiding and steering forces.

2. The apparatus according to claim 1 wherein the gas lift system comprises two gas lift planks each along a respective side of the magnet and each including a series of spaced gas lift members therealong.

3. The apparatus according to claim 1 wherein the gas lift planks include floor engagement members are spaced positions therealong relative to the series of spaced gas lift members.

4. The apparatus according to claim 1 wherein the gas lift system comprises a primary lift system used for primary lifting and a secondary lift system used when a failure occurs in the primary lift system.

5. The apparatus according to claim 1 wherein the primary and secondary lift system are arranged in rows along respective sides of the magnet.

6. The apparatus according to claim 1 wherein the drive system comprises at least one rotatable drive member rotatable about a horizontal axis for engaging the floor when raised on the gas lift system for driving the magnet across the floor.

7. The apparatus according to claim 1 wherein the drive system comprises two sets of rotary members on respective sides of the magnet with differential rotation speed for steering.

8. The apparatus according to claim 1 wherein the rotary members are spring biassed into engagement with floor in both raised and lowered positions of the support system.

9. The apparatus according to claim 1 wherein the drive system includes a back up in the event of failure.

10. The apparatus according to claim 1 wherein the drive system comprise a guide track applied on the floor and a camera on the support system supplying an image to a controls system for following the guide track.

11. The apparatus according to claim 1 wherein the support system comprises a guide pin at a center of the support system for engaging a receptacle at the floor in the retracted position for rotating the support system and the magnet around an axis of the guide pin.

12. The apparatus according to claim 1 wherein the support system comprises first and second support plates at the floor at the imaging and retracted positions for receiving loading forces from the gas lift system.

13. The apparatus according to claim 1 wherein the support system includes at least one seismic clamp for engaging a receptacle in the floor at the imaging portion for connecting the support system and the magnet to the floor.

14. The apparatus according to claim 1 wherein the support system includes resilient support elements between the support system and the magnet.

15. A magnetic resonance imaging system for obtaining images of a part of the patient comprising:
a cylindrical magnet of magnet wire defining a cylindrical bore within which a part of the patient is located for placement within high magnetic fields generated by the magnet;
a detection system for eliciting and detecting from the part of the patient nuclear magnetic resonance signals in response to the magnetic field; and
a support system arranged to be supported from a floor and mounting the magnet for movement relative to the floor, the support system comprising:
a lift system which applies a lifting force from the floor and carries at least some of the weight of the magnet at least some of the time;
a drive control system, separate from the lift system, applying to the magnet guiding forces and steering forces operated by signals from a drive input control.

16. A magnetic resonance imaging system for obtaining images of a part of the patient comprising:
a cylindrical magnet of magnet wire defining a cylindrical bore within which a part of the patient is located for placement within high magnetic fields generated by the magnet;
a detection system for eliciting and detecting from the part of the patient nuclear magnetic resonance signals in response to the magnetic field; and
a support system arranged to be supported from a floor and mounting the magnet for movement relative to the floor, the support system comprising:
drive arrangements for engaging the floor and carrying the magnet;
the drive arrangements arranged to be driven by a drive control system;
and a separate lifting system for lifting the drive arrangements and the magnet carried thereby up from the floor sufficiently to allow the magnet to be moved relative to the floor independently of the drive control system of the drive arrangements.
